(19) United States
(12) Patent Application Publication
(10) Pub. No.: US 2024/0258991 A1
(43) Pub. Date: Aug. 1, 2024

(54) METHODS OF PACKAGING ACOUSTIC WAVE RESONATOR DEVICES ON WAFERS AND RELATED WAFERS AND STRUCTURES

(71) Applicant: Akoustis, Inc., Huntersville, NC (US)

(72) Inventors: Kenneth Fallon, Rochester, NY (US); Carlos R. Padilla, Pittsford, NY (US); Mary Winters, Webster, NY (US); Robert Charles Dry, Cornelius, NC (US); Ethan Gram, Mooresville, NC (US); Westbrook Hoose, Huntersville, NC (US)

(21) Appl. No.: 18/160,877

(22) Filed: Jan. 27, 2023

(51) Int. Cl. H03H 9/10; H03H 3/02; H03H 9/05; H03H 9/17

(52) U.S. Cl. CPC H03H 9/105; H03H 3/02; H03H 9/0523; H03H 9/173

(57) ABSTRACT

A wafer including an array of bulk acoustic wave resonator devices can include a first bulk acoustic wave resonator device on the wafer, the first bulk acoustic wave resonator device including a passivation layer on a piezoelectric layer, a second bulk acoustic wave resonator device on the wafer directly adjacent to the first bulk acoustic wave resonator device, the second bulk acoustic wave resonator device including the passivation layer and the piezoelectric layer, a wall layer on the wafer forming first and second wall cavity structures that extend around the first and second bulk acoustic wave resonator devices, respectively, a capping layer extending over the wall layer to cover the first and second wall cavity structures that include the first and second bulk acoustic wave resonator devices, respectively, a metallization layer coupling together bulk acoustic wave resonators included in the first or second bulk acoustic wave resonator device and a pillar that protrudes vertically from the metallization layer to contact the cap layer.

### FIELD

The inventive concept relates generally to wafer-level packaging and, more particularly, to wafer-level packaging for Micro-Electro-Mechanical Systems.

### BACKGROUND

Wafer-Level Packaging (WLP) is a packaging technology performed at the wafer level. For example, when an array of devices are formed together on a wafer, WLP can be performed by packaging those devices before the devices are singulated (or “diced”) to provide separate devices for use, sale, and/or integration in a larger system. Wafer-level packaging can allow the integration of wafer fab, packaging, test, and burn-in at the wafer level to streamline the manufacturing process undergone by a device. WLP can be used in the manufacturing of mobile devices, such as smartphones, due to the size constraints imposed by relatively small product sizes, including thickness.

### SUMMARY

Embodiments according to the present inventive concept can provide methods of packaging acoustic wave resonator devices and related wafers and structures. Pursuant to these embodiments, a wafer including an array of bulk acoustic wave resonator devices can include a first bulk acoustic wave resonator device on the wafer, the first bulk acoustic wave resonator device including a passivation layer on a piezoelectric layer, a second bulk acoustic wave resonator device on the wafer directly adjacent to the first bulk acoustic wave resonator device, the second bulk acoustic wave resonator device including the passivation layer and the piezoelectric layer, a wall layer on the wafer forming first and second wall cavity structures that extend around the first and second bulk acoustic wave resonator devices, respectively, a capping layer extending over the wall layer to cover the first and second wall cavity structures that include the first and second bulk acoustic wave resonator devices, respectively, a metallization layer coupling together bulk acoustic wave resonators included in the first or second bulk acoustic wave resonator device and a pillar that protrudes vertically from the metallization layer to contact the cap layer.

### BRIEF DESCRIPTION OF THE DRAWINGS

FIG. 1A is a schematic representation of a device wafer including a plurality of bulk acoustic wave resonator devices arranged in an X-Y pattern and separated by dicing streets in some embodiments according to the inventive concept.

FIG. 1B is a schematic representation of the region B shown in FIG. 1A illustrating a single bulk acoustic wave resonator device including a plurality of bulk acoustic wave resonators arranged into a configuration to provide the device shown in FIG. 1A in some embodiments according to the inventive concept.

FIG. 2A-C are schematic representations of a single bulk acoustic wave resonator illustrative of the bulk acoustic wave resonators shown in FIGS. 1A-B in some embodiments according to the inventive concept.

FIGS. 3-25 are cross-sectional views illustrating methods of packaging the bulk acoustic wave resonator devices on the device wafer shown in FIG. 1A sealed inside respective wall cavity structures and cap layers formed of an epoxy-based photoresist material deposited across the device wafer in some embodiments according to the inventive concept.

FIGS. 26A-B are schematic illustrations of a plan view of a device wafer with dies and a cross-sectional view of two directly adjacent dies including a dicing street between the two directly adjacent dies in some embodiments according to the inventive concept.

### DETAILED DESCRIPTION OF EMBODIMENTS ACCORDING TO THE INVENTIVE CONCEPT

According to embodiments of the present inventive concept, techniques generally related to the packaging of electronic devices are provided herein. More particularly, the present inventive concept can provide techniques related to methods of forming (and structures related to) bulk acoustic wave resonator devices and the like.

Merely by way of example, embodiments according to the present inventive concept described here are applied to a bulk acoustic wave piezoelectric resonator device for communication devices, mobile devices, computing devices, etc. It will be understood, however, that the embodiments of the present inventive concept described herein can be applied to other applications.

Merely by way of example, embodiments according to the inventive concept are illustrated herein using a limited number of bulk acoustic wave piezoelectric resonator devices on a wafer. It will be understood, however, that the number of devices on the wafer may be more than that illustrated.

As appreciated by the present inventors, an epoxy based photoresist material can be used to form a wall cavity structure to surround bulk acoustic wave resonator devices at the wafer level. The wall cavity structure can be defined by a cavity wall (formed of the epoxy based photoresist material) that extends around the bulk acoustic wave resonator device. Furthermore, the bulk acoustic wave resonator devices can be sealed inside the wall cavity structures by forming a cap layer of the epoxy based photoresist material to extend over the cavity wall across the wall cavity structure over the devices. In some embodiments according to the inventive concept, the bulk acoustic wave resonator devices are configured to operate in a frequency range between about 1 GHz to about 20 GHz. Accordingly, filters that include the bulk acoustic wave resonator devices packaged as described herein can provide, for example, a filter with a response having a center frequency in a range between about 1 GHz to about 20 GHz.

As further appreciated by the present inventors, the wall cavity structure and the cap layer can be formed across the wafer on which the bulk acoustic wave resonator devices are formed so that each of the devices can be packaged while on the device wafer. Subsequently, the packaged bulk acoustic wave resonator devices can be singulated by dicing the device wafer. The singulated packaged bulk acoustic wave resonator devices can be included as components in products to provide a thinner overall product thickness, such as in mobile devices.

As appreciated by the present inventors, the epoxy based photoresist material can be selected to be compatible with the temperature profiles used to fabricate other structures in the bulk acoustic wave resonator device.

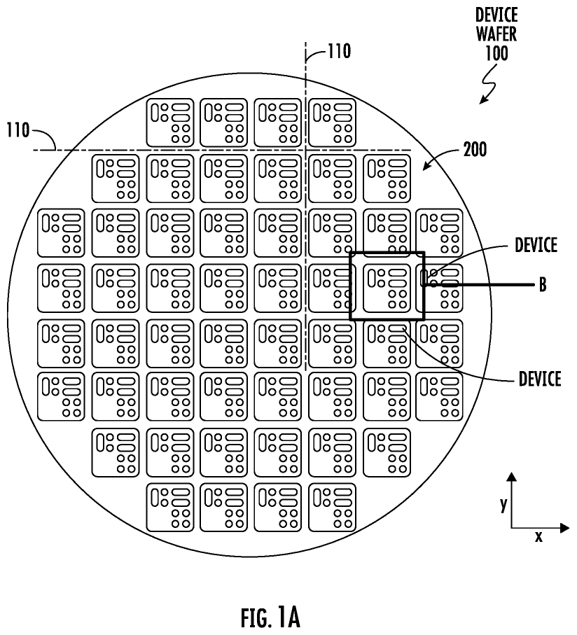

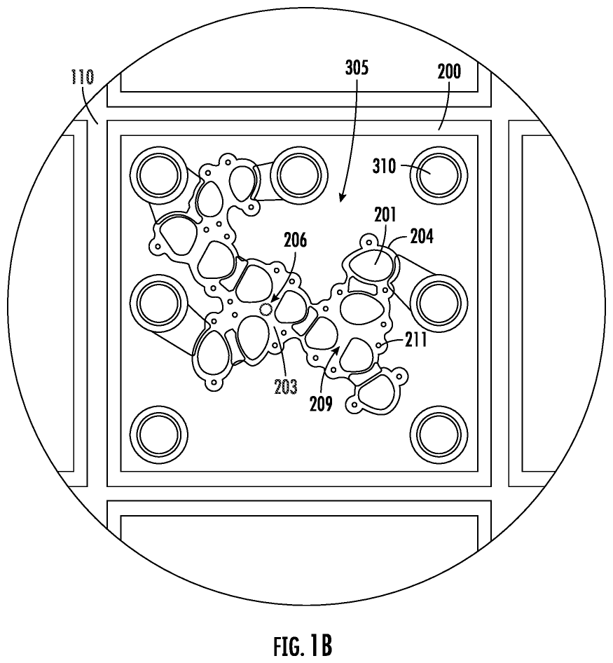

FIG. 1A is a schematic representation of a device wafer 100 including a plurality of bulk acoustic wave resonator devices 305 on respective dies 200 arranged in an X-Y pattern and separated by dicing streets 110 in some embodiments according to the inventive concept. According to FIG. 1A, the dicing streets 110 extend in the X and Y directions to separate each of the bulk acoustic wave resonator devices 305 from one another. As described herein, the bulk acoustic wave resonator devices 305 can be packaged on the device wafer 100 using the epoxy-based photoresist material to form the wall cavity structures that surround the bulk acoustic wave resonator devices 305 and the cap layers that seal the bulk acoustic wave resonator devices 305 in the wall cavity structures. The device wafer 100 can then be “diced” to separate the packaged bulk acoustic wave resonator devices 305 from one another.

Although some embodiments according to the inventive concept described herein detail that the packaged bulk acoustic wave resonator devices 305 are separated from one another by dicing the device wafer, in other embodiments the entire device wafer 100 with the packaged bulk acoustic wave resonator devices 305 thereon may be provided as a single unit.

FIG. 1B is a schematic representation of the die 200 shown in FIG. 1A including a single acoustic bulk acoustic wave resonator device 305 surrounded by other device dies 200. As shown in FIG. 1B, the acoustic bulk acoustic wave resonator device 305 can include a plurality of bulk acoustic wave resonators 201 that are coupled together by interconnects 203 (sometimes referred to herein as metallization) in some embodiments according to the inventive concept. It will be understood that although the device 305 illustrates a plurality of resonators 201 coupled together to form the device 305, in some embodiments the device 305 can include a single resonator 201. Other configurations of resonators 201 may also be provided for the device 305.

As further shown in FIG. 1B, the acoustic bulk acoustic wave resonator device 305 is surrounded by a cavity wall 204 that defines a wall cavity structure 209 in some embodiments according to the inventive concept. Bonding pads 310 are located on the die 200 outside the wall cavity structure 209. In some embodiments according to the inventive concept, the cavity wall 204 for each of the acoustic bulk acoustic wave resonator devices 305 can be provided by forming a wall layer on device wafer 100 and removing those portions of the wall layer that cover the bulk acoustic wave resonators 201 in each device 305.

Removing the portion of the wall layer over the resonators forms the cavity wall 204 that surrounds the resonators and defines the wall cavity structure 209 for each device 305 in some embodiments according to the inventive concept. In some embodiments according to the inventive concept, a cap layer can be formed over the cavity wall 204 and extends across the wall cavity structure 209 over the bulk acoustic wave resonators 201 within the wall cavity structure 209.

As further shown in FIG. 1B, the acoustic bulk acoustic wave resonator device 305 can include bonding pads 310 located outside cavity wall 204 and are coupled to, for example, electrodes of selected ones of the bulk acoustic wave resonators 201. In some embodiments according to the invention, the portions of the wall layer and the cap layer 212 formed over the bonding pads 310 may also be processed to expose at least a portion of a surface of the bonding pads 310 so that conductive material can be deposited on the bonding pads 310 therein to provide interconnect to the device 305.

As further shown in FIG. 1B, release holes 211 can be formed as part of the bulk acoustic wave resonators 201 in some embodiments. The release holes can be formed to expose a resonator cavity located between a lower electrode of the bulk acoustic wave resonator 201 and the underlying bond substrate. The release holes can allow for improved cleaning of the resonator cavity when removing, for example, a sacrificial material that is formed to define where the resonator cavity will be subsequently located beneath the electrode.

As further shown in FIG. 1B, pillars 206 may also be formed within the wall cavity structure 209 between selected ones of the bulk acoustic wave resonators 201 in some embodiments according to the inventive concept. The pillars 206 can extend vertically from an upper surface of the interconnect used to couple to the resonators 201 in the bulk acoustic wave resonator device 305. When the cap layer 212 is formed over the wall cavity structure 209 to seal in the bulk acoustic wave resonator device 305, the pillars 206 can support the cap layer 212 to reduce structural deformation.

It will be further understood that, in some embodiments according to the inventive concept, the cavity wall 204 and the resulting wall cavity structure 209 can surround a group of bulk acoustic wave resonators 201 within the bulk acoustic wave resonator device 305. In some embodiments according to the invention, the wall cavity structure 209 can surround a single resonator 201.

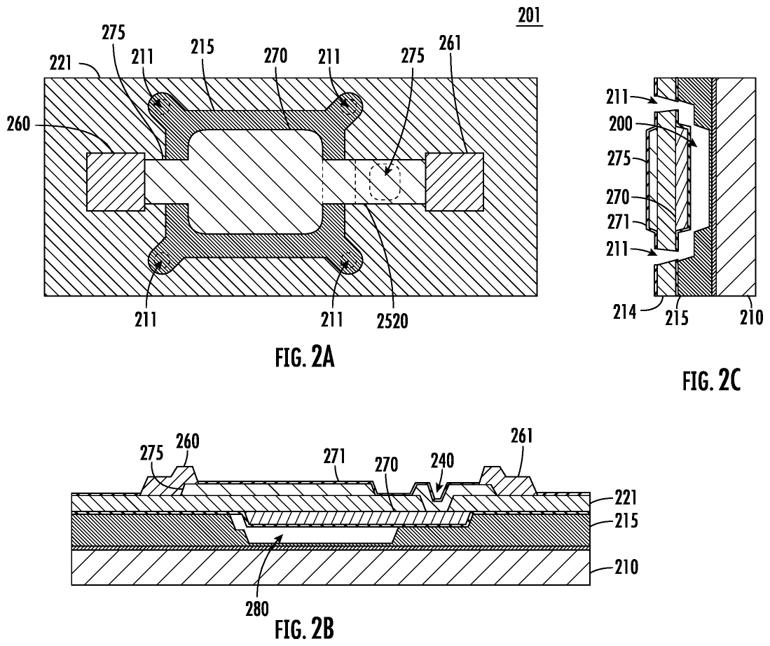

FIG. 2A-C are schematic representations of a single bulk acoustic wave resonator illustrative of the bulk acoustic wave resonators 201 shown in FIGS. 1A-B in some embodiments according to the inventive concept. As shown in FIGS. 2A-C, the bulk acoustic wave resonator 201 can include a piezoelectric layer 221 sandwiched between a lower electrode 270 and an upper electrode 275. A resonator cavity 280 is formed in a support structure 215 beneath lower electrode 270. The bulk acoustic wave resonator 201 is located on a bond substrate 210 to which the support structure 215 was bonded as part of a transfer process used to form the bulk acoustic wave resonator 201. The upper electrode 275 is coupled to an upper metal 260 and the lower electrode 270 is coupled to a lower metal 261 by a via 240 that extends through the piezoelectric layer 221. The pillar 206 shown in FIG. 1B can be formed outside the active area of the bulk acoustic wave resonator 201 to support the cap layer 212 in some embodiments according to the inventive concept.

As further shown in FIG. 2C, the release holes 211 extend around the edges of the piezoelectric layer 221 to the resonator cavity 280. During fabrication of the bulk acoustic wave resonators 201, a sacrificial material is formed on the lower electrode 270 to preserve the region which will ultimately be used to provide the resonator cavity 280. The sacrificial material is removed through the release holes 211 to form the resonator cavity 280.

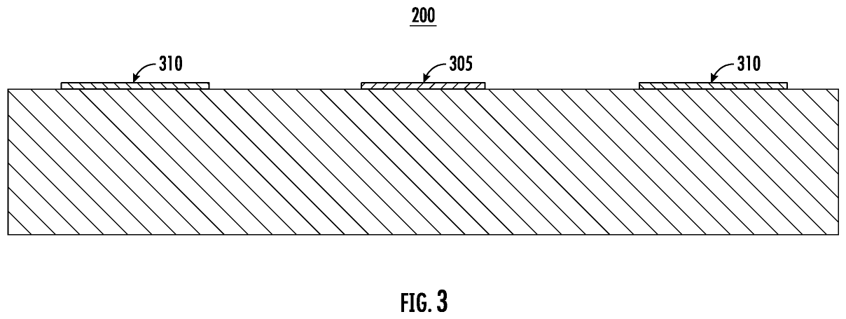

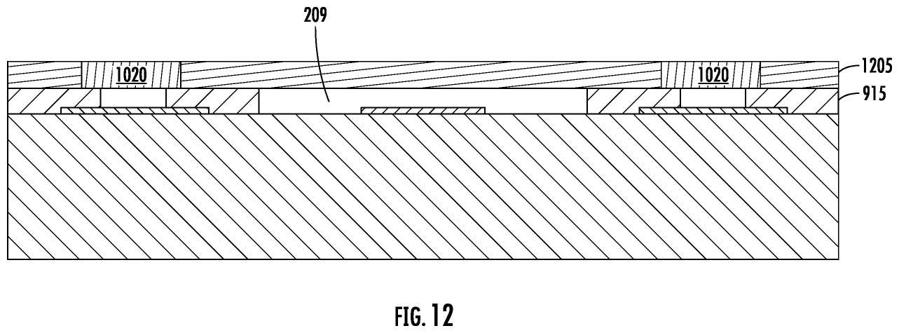

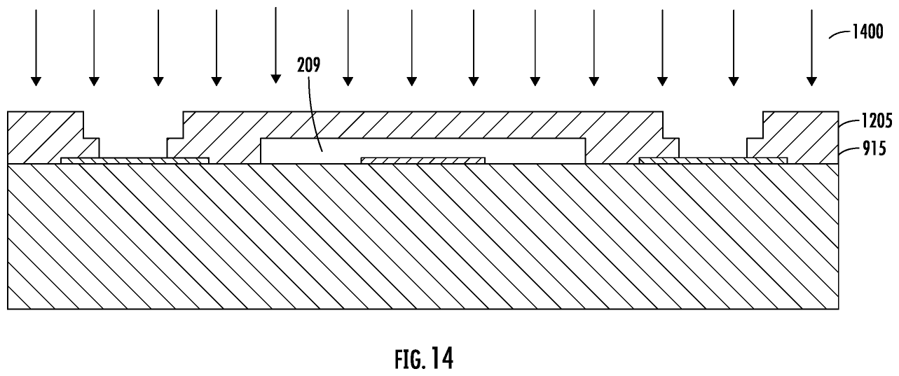

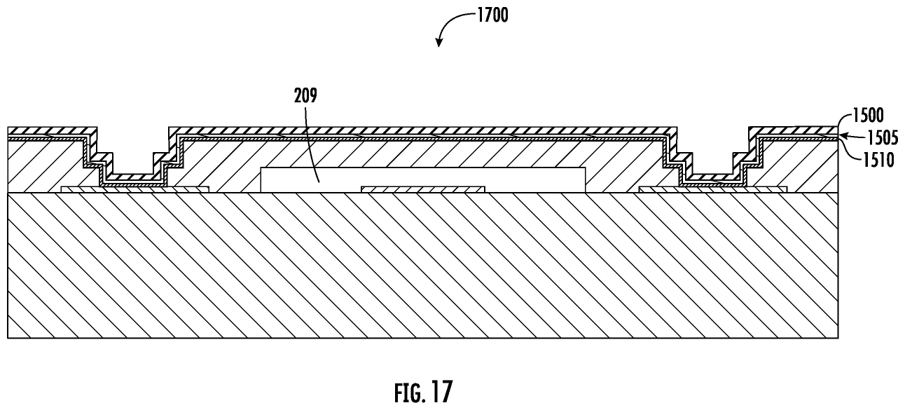

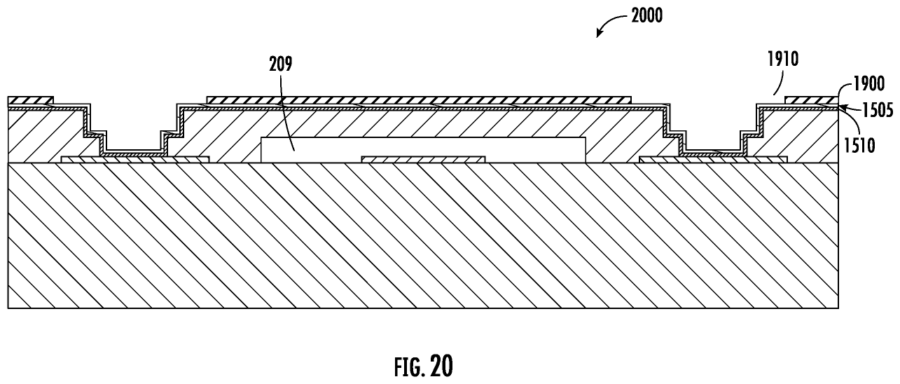

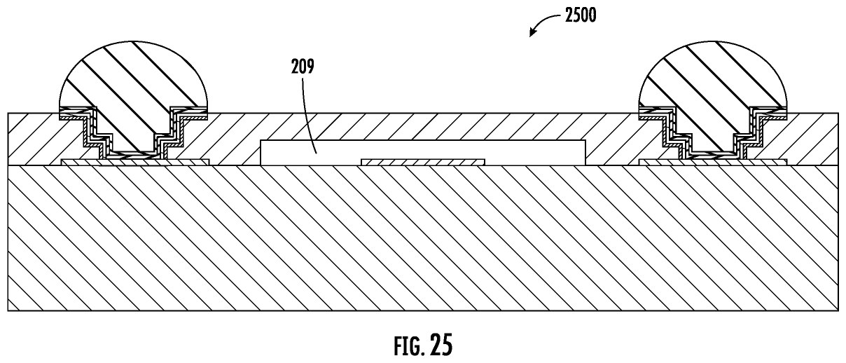

FIGS. 3-26 are cross-sectional views illustrating methods of packaging bulk acoustic wave resonator devices 305 on the device wafer 100 shown in FIG. 1A sealed inside respective wall cavity structures 209 and cap layers 212 formed of an epoxy-based photoresist material deposited across the device wafer 100 in some embodiments according to the inventive concept. It will be understood that, although FIGS. 3-26 show a single bulk acoustic wave resonator device 305 and associated bonding pads 310, the operations described herein with reference to FIGS. 3-26 can be applied to all of the bulk acoustic wave resonator devices 305 on the device wafer 100.

According to FIG. 3, the bulk acoustic wave resonator device 305 and the bonding pads 310 are formed on the die 200. It will be understood that the depiction of the bulk acoustic wave resonator device 305 and the bonding pads 310 are not necessarily shown to scale.

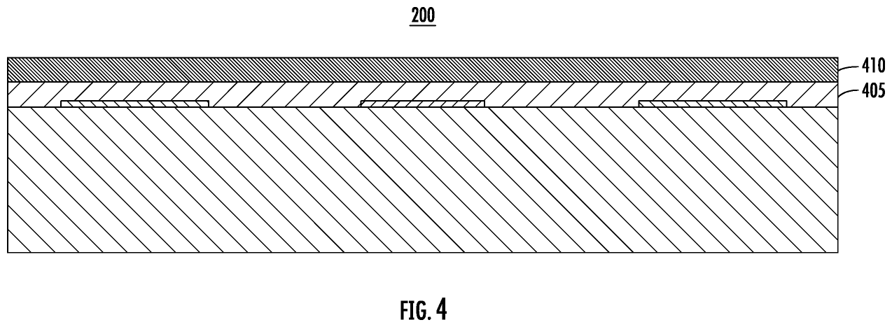

As shown in FIG. 4, in some embodiments according to the inventive concept, an epoxy-based photoresist material is deposited on the cleaned bulk acoustic wave resonator device 305 and the bonding pads 310 to provide a wall layer 405 thereon and a protective film 410. In some embodiments according to the inventive concept, material can be another light sensitive material. In some embodiments according to the inventive concept, the photoresist can be made into a viscous polymer that can be spun or spread over the cleaned bulk acoustic wave resonator device 305 and the bonding pads 310 for lamination. The epoxy-based photoresist material can react to exposure whereby the portions of the photoresist layer exposed to radiation become cross-linked (i.e., resistant to removal), while the un-exposed portions of the layer become removable portions that can be removed during a subsequent development process. In some embodiments according to the inventive concept, the photoresist layer can be used to pattern high aspect ratio structures.

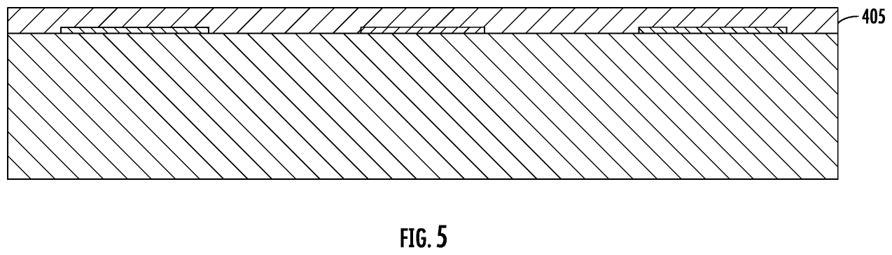

According to FIG. 5, the protective film 410 is removed from the wall layer 405. The exposed wall layer 405 is heated to, for example, improve the adhesion of the wall layer 405 on the surface of the device wafer 100, the bulk acoustic wave resonator device 305 and the bonding pads 310.

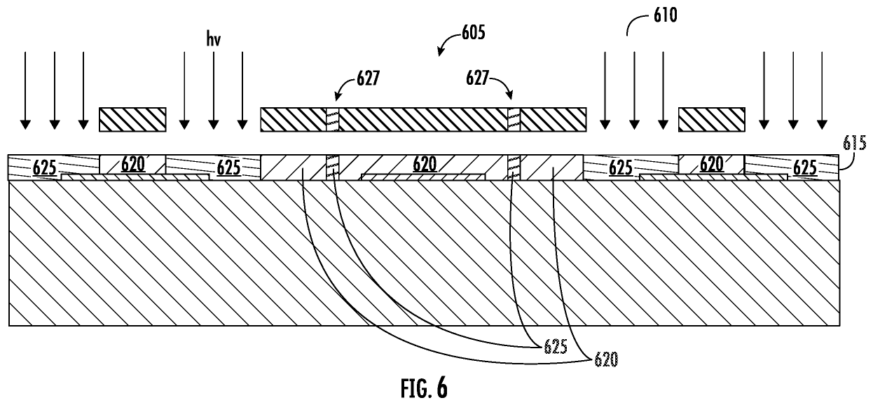

According to FIG. 6, the wall layer 405 is patterned by exposure to UV radiation 610 through a mask 605 having portions that block the UV radiation from impacting regions of the wall layer 405 that correspond to where the cavity wall structure 209 is to be formed and that correspond to regions of the wall layer 405 where surfaces of the bonding pads 310 are to be exposed. The exposure via the mask 605 results in the formation of a patterned wall layer 615 including removable portions 620 and portions that are resistant to removal 625 (i.e., remaining portions).

As further shown in FIG. 6, the central portion of the mask 605 located over the bulk acoustic resonator device may also include holes 627 that allow the impinging UV radiation 610 to impact the wall layer 615 to form remaining portions 625 on the metallization 206 used to connect some of the bulk acoustic resonators to form vertical pillars to provide support for the cap layer.

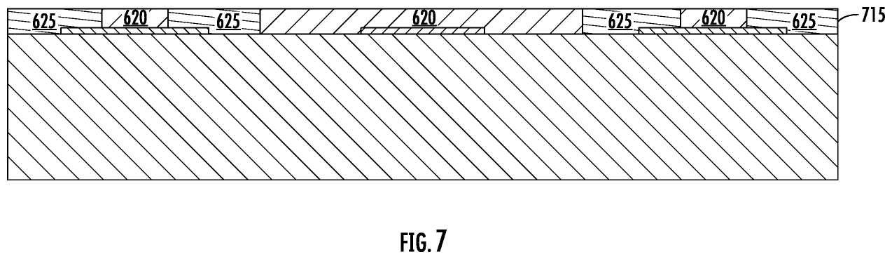

According to FIG. 7, the patterned wall layer 615 is cured by heating to a temperature that is about equal to temperatures used in subsequent processes such as during a bumping process where conductive material is deposited onto the exposed surfaces of the bonding pads 310 after the cap layer is formed to seal the bulk acoustic wave resonator devices 305.

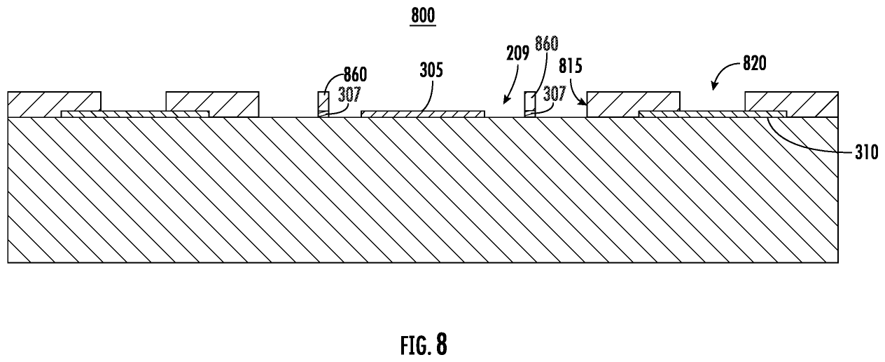

According to FIG. 8, in some embodiments according to the inventive concept, the cured wall layer 715 is developed to remove the removable portions 620 over the bonding pads 310 and the bulk acoustic resonator devices 305 and to leave the remaining portions 625. The remaining portions 625 form cavity walls 815 that surround each of the bulk acoustic resonator devices 305 on the device wafer 100. The cavity walls 815 also define the wall cavity structures 810 in which each of the bulk acoustic resonator devices 305 are located. The remaining portions 625 overlapping the bonding pads also leave a portion of the surface of the bonding pads 310 exposed by forming openings 820 as shown. In some embodiments according to the inventive concept, the remaining portions 625 are formed on the metallization 307 between some of the bulk acoustic resonators 201 to form vertical pillars 860 within the cavity structure 810 between the cavity wall 815 and the bulk acoustic resonator device 305 as shown.

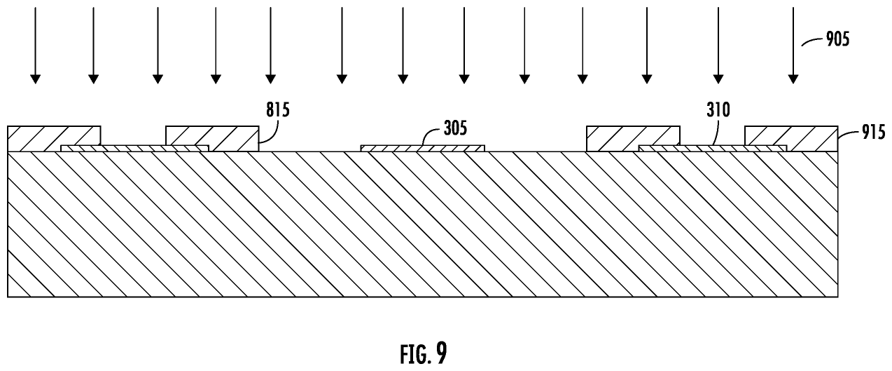

According to FIG. 9, the cleaned device wafer 100 is exposed to a heat source 905 to harden the epoxy-based photoresist material that forms the cavity wall 815 and over the bonding pad wall 821.

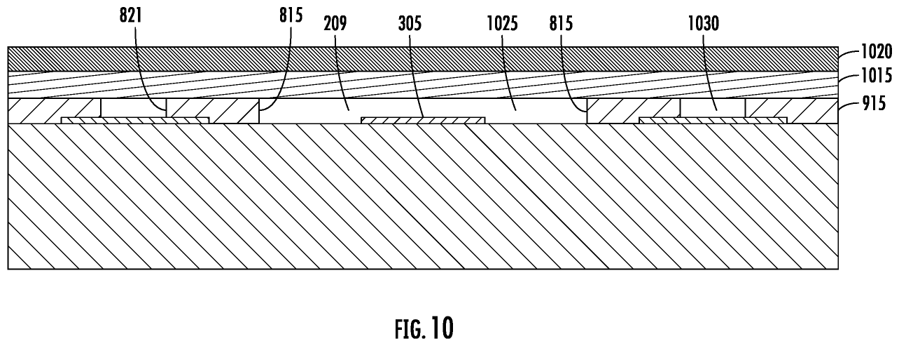

According to FIG. 10, the epoxy-based photoresist material is deposited over the cavity wall 815 and the bonding pad wall 821 to extend over the bulk acoustic wave resonators device 305 and the bonding pads 310, respectively, to form a cap layer 1015 and a protective film 1020 thereon. Forming the cap layer 1015 that seals the bulk acoustic wave resonator device 305 inside the wall cavity structure 810. In some embodiments according to the inventive concept, the epoxy-based photoresist material is deposited by a roller.

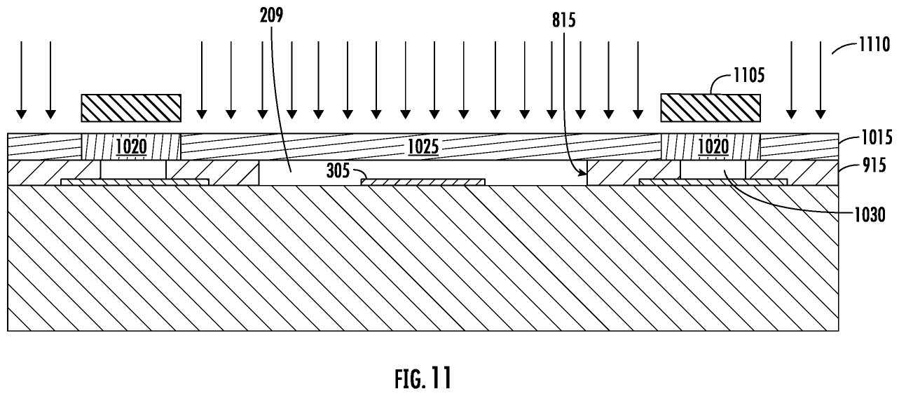

According to FIG. 11, the device wafer 100 is exposed to a UV radiation 1110 using a mask 1105, which blocks the UV radiation 1110 to form removable portions 1020 over the bonding pads 310, which are to be subsequently removed while forming remaining portions 1025 where the UV radiation impinges the cap layer 1015 to form a patterned cap layer 1205. As shown in FIG. 11, the removable portions 1020 are wider than the openings over the bonding pads 310 formed in FIG. 6-8 herein.

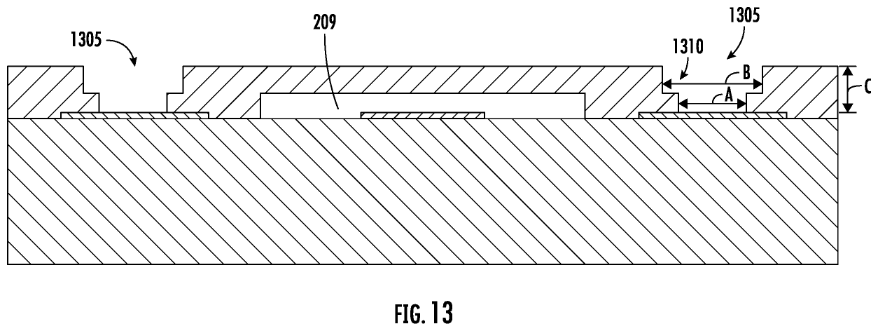

According to FIG. 13, after the post exposure bake the patterned cap layer 1205 is subjected to a development process to remove the removable portions 1020 from the patterned cap layer 1205 to form the openings 1305. In some embodiments according to the inventive concept, the openings 1305 have a width “B” that is greater than the width “A” of the openings formed in the wall layer 915 while the overall thickness of the wall layer 915 and the patterned cap layer 1205 having a thickness of “C.” Accordingly in some embodiments according to the inventive concept, the openings 1305 have can have a stepped sidewall profile 1310 as shown.

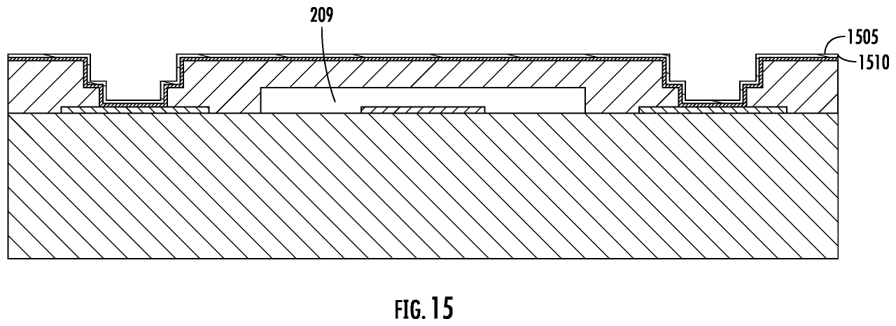

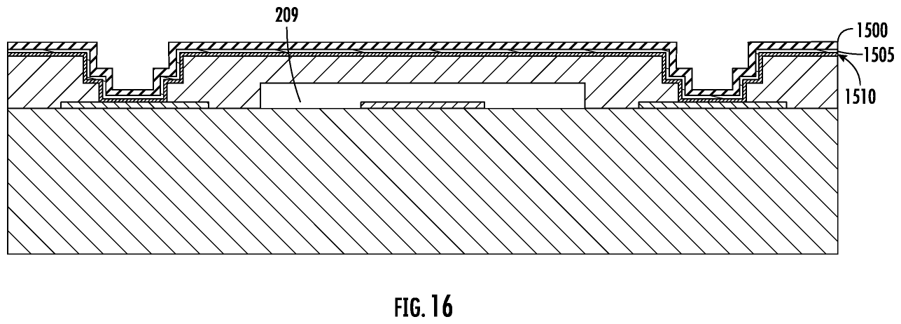

According to FIG. 15, an adhesion film 1510, comprising for example titanium, is sputtered onto the surface of the cap layer 1405 and in the openings 1305. A copper film 1505 is sputtered onto the adhesion film 1510. According to FIG. 16 a layer of epoxy-based photoresist material is deposited on the copper film 1505 to form a photoresist layer 1500.

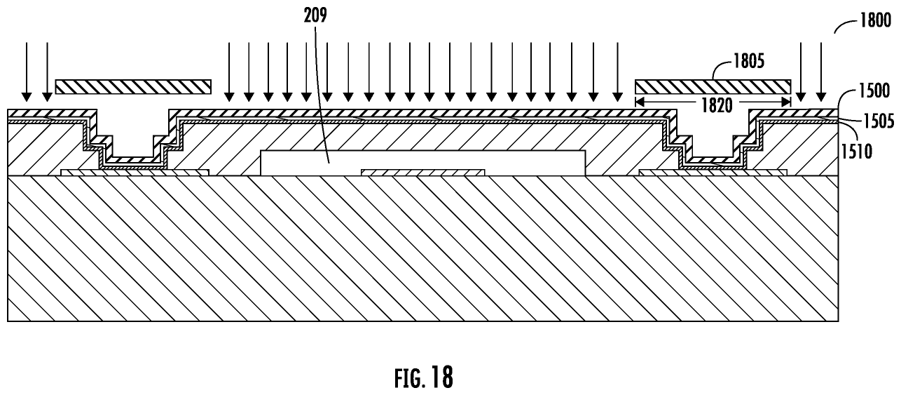

According to FIG. 18, photoresist layer 1500 is patterned by exposure to UV radiation 1800 through a mask 1805 having portions that block the UV radiation 1800 from impacting the openings 1305 and directly adjacent regions of the photoresist layer 1500. The exposure via the mask 1805 results in the formation of a patterned photoresist layer including removable portions 1820 and portions that are resistant to removal (i.e., remaining portions).

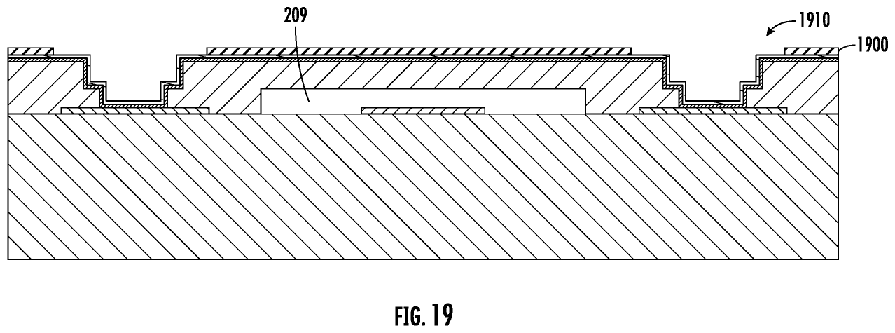

According to FIG. 19, after exposure, the patterned photoresist layer is subjected to a development process to remove the removable portions 1820 from the patterned photoresist layer leaving the patterned photoresist layer on the copper film over the bulk acoustic wave resonator device 305 and the bonding pads 310.

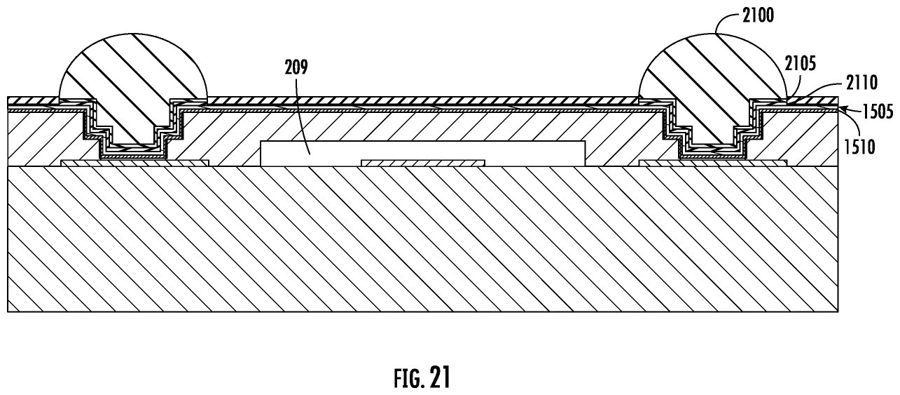

According to FIG. 21, copper is plated onto the copper film 1505 on the surface of the device wafer 100 where the patterned photoresist layer was removed (i.e., the removable portions 1820) to form a plated copper film 2110.

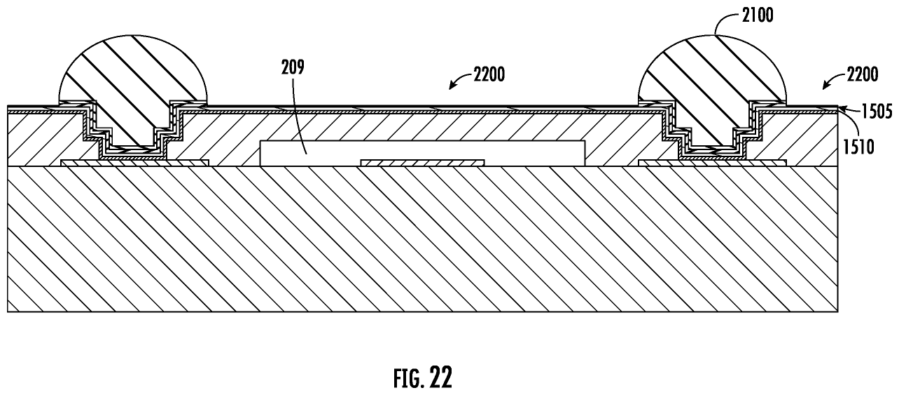

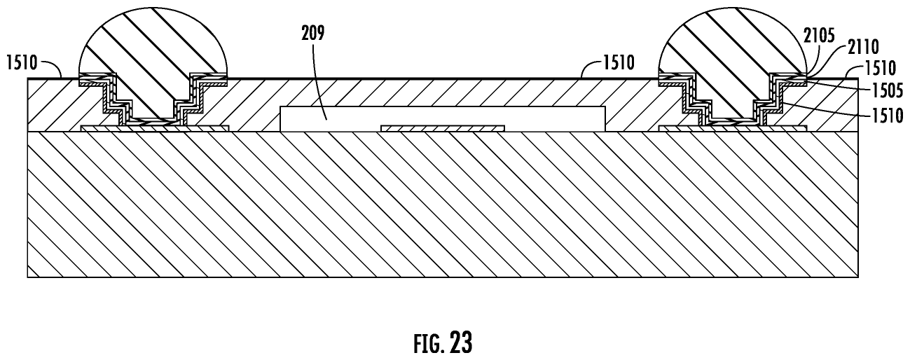

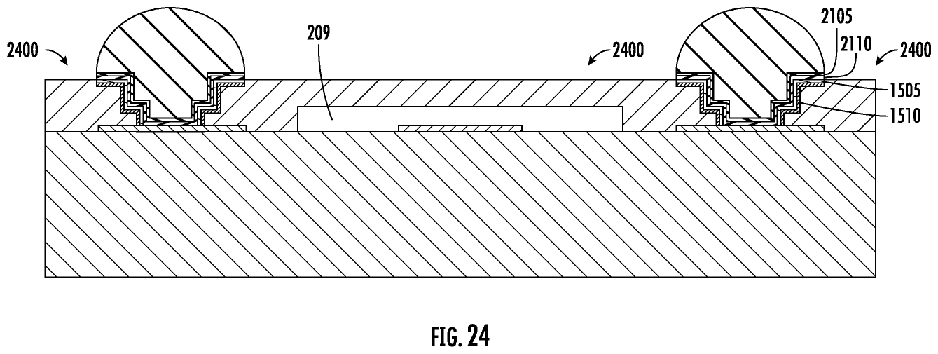

According to FIG. 22, the remaining patterned photoresist layer is stripped from the surface 2200 of the device wafer 100. According to FIG. 23, the sputtered copper film 1505 outside the conductive bump 2100 is etched from the surface of the device wafer 100 to expose the sputtered titanium film 1510. According to FIG. 24, the sputtered titanium film 1510 is etched to expose the surface 2400 of the device wafer 100.

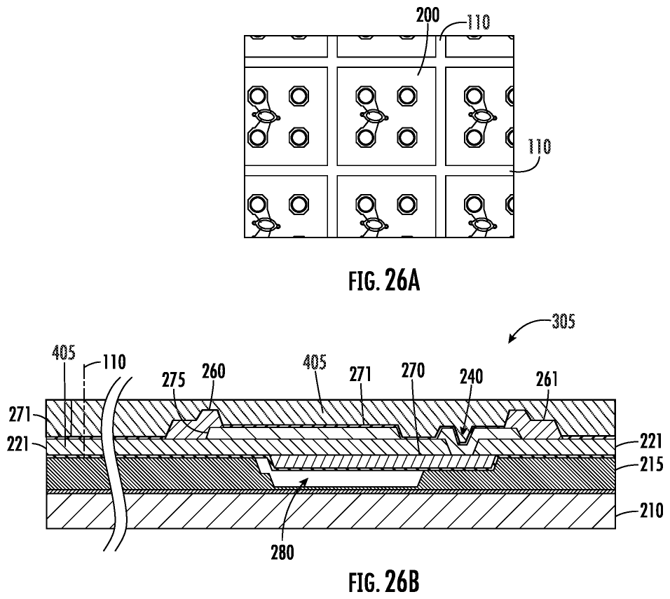

FIG. 26A-B are schematic illustrations of a plan view of a device wafer 100 with dies 200 and a cross-sectional view of two directly adjacent dies 200 including a dicing street 110 between the two directly adjacent dies 200 in some embodiments according to the inventive concept. According to FIGS. 26A-B, the bulk acoustic resonator devices 305 and the associated bonding pads 310 are covered by the epoxy-based photoresist material as described herein with reference to FIGS. 1-25.

In particular, as shown in FIG. 26B, the wall layer and the cap layer are shown to cover the bulk acoustic resonator devices 305.

As used herein, the term “directly adjacent” includes arrangements where two elements are in proximity to one another so that no other ones of the same elements are located between the elements that are described as being directly adjacent. For example, if two layers are described as being directly adjacent to one another it will be understood that there are no other layers of the same type located between the two layers. In some embodiments, if the two layers are described as being in contact with one another, there are no other intervening elements between the two layers at least where the portions of the two layers are described as being in contact.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. Additionally, as used herein, the term “and/or” includes any and all combinations of one or more of the associated listed items and may be abbreviated as “/”.

The term “comprise,” as used herein, in addition to its regular meaning, may also include, and, in some embodiments, may specifically refer to the expressions “consist essentially of” and/or “consist of.” Thus, the expression “comprise” can also refer to, in some embodiments, the specifically listed elements of that which is claimed and does not include further elements, as well as embodiments in which the specifically listed elements of that which is claimed may and/or does encompass further elements, or embodiments in which the specifically listed elements of that which is claimed may encompass further elements that do not materially affect the basic and novel characteristic(s) of that which is claimed. For example, that which is claimed, such as a composition, formulation, method, system, etc. “comprising” listed elements also encompasses, for example, a composition, formulation, method, kit, etc. “consisting of,” i.e., wherein that which is claimed does not include further elements, and a composition, formulation, method, kit, etc. “consisting essentially of,” i.e., wherein that which is claimed may include further elements that do not materially affect the basic and novel characteristic(s) of that which is claimed.

The term “about” generally refers to a range of numeric values that one of skill in the art would consider equivalent to the recited numeric value or having the same function or result. For example, “about” may refer to a range that is within ±1%, ±2%, ±5%, ±7%, ±10%, ±15%, or even ±20% of the indicated value, depending upon the numeric values that one of skill in the art would consider equivalent to the recited numeric value or having the same function or result. Furthermore, in some embodiments, a numeric value modified by the term “about” may also include a numeric value that is “exactly” the recited numeric value. In addition, any numeric value presented without modification will be appreciated to include numeric values “about” the recited numeric value, as well as include “exactly” the recited numeric value. Similarly, the term “substantially” means largely, but not wholly, the same form, manner or degree and the particular element will have a range of configurations as a person of ordinary skill in the art would consider as having the same function or result. When a particular element is expressed as an approximation by use of the term “substantially,” it will be understood that the particular element forms another embodiment.

Many different embodiments have been disclosed herein, in connection with the above description and the drawings. It will be understood that it would be unduly repetitious and obfuscating to literally describe and illustrate every combination and subcombination of these embodiments. Accordingly, all embodiments can be combined in any way and/or combination, and the present specification, including the drawings, shall support claims to any such combination or subcombination.

What is claimed:

1. A method of forming a packaging structure for bulk acoustic wave resonator devices spaced apart on a wafer, the method comprising:
depositing an epoxy-based photoresist material on the wafer to form an epoxy-based photoresist layer to cover the bulk acoustic wave resonator devices, wherein each of the bulk acoustic wave resonator devices includes a plurality of bulk acoustic wave resonators each comprising:
a piezoelectric resonator reflector cavity located between a piezoelectric layer and a bulk acoustic wave resonator substrate; and
release holes that extend through the piezoelectric layer to the piezoelectric resonator reflector cavity;
processing the epoxy-based photoresist layer to form removable portions of the epoxy-based photoresist layer and to form remaining portions of the epoxy-based photoresist layer that are resistant to removal;
developing the epoxy-based photoresist layer to remove the removable portions to form wall cavity structures that are each defined by a cavity wall that extends around the bulk acoustic wave resonator device in the wall cavity structure; and
depositing the epoxy-based photoresist material to form a cap layer extending over the cavity walls to seal each of the bulk acoustic wave resonator devices within the respective wall cavity structure defined by the cavity walls.

2. The method of claim 1 wherein processing the epoxy-based photoresist layer further comprises:
patterning the epoxy-based photoresist layer using photolithography to form a patterned epoxy-based photoresist layer that includes the removable portions and the remaining portions; and
curing the patterned epoxy-based photoresist layer.

3. The method of claim 1 wherein patterning the epoxy-based photoresist layer further comprises:
patterning epoxy-based photoresist layer so that the remaining portions include pillars that are defined to protrude vertically in each of the wall cavity structures between the cavity wall and the bulk acoustic wave resonator device in the wall cavity structure.

4. The method of claim 3 wherein the bulk acoustic wave resonator devices each include a metallization layer coupling together bulk acoustic wave resonators, wherein the patterning the epoxy-based photoresist layer further comprises:
patterning epoxy-based photoresist layer so that the remaining portions include the pillars on the metallization layer in each of the wall cavity structures between ones of the bulk acoustic wave resonator devices in the wall cavity structure.

5. The method of claim 1 wherein depositing the epoxy-based photoresist material on the wafer to form the epoxy-based photoresist layer comprises depositing the epoxy-based photoresist material on the wafer to cover the bulk acoustic wave resonator devices and bonding pads that are coupled to respective ones of the bulk acoustic wave resonator devices;
wherein processing the epoxy-based photoresist layer comprises patterning the epoxy-based photoresist layer to form a patterned epoxy-based photoresist layer that includes the removable portions on the bulk acoustic wave resonator devices and on the bonding pads; and
wherein developing the epoxy-based photoresist layer comprises removing the removable portions to form the cavity structures and to expose surfaces of the bonding pads.

6. The method of claim 5 further comprising:
wherein depositing the epoxy-based photoresist material to form the cap layer comprises depositing the epoxy-based photoresist material to form the cap layer to seal each of the bulk acoustic wave resonator devices within the respective wall cavity structure and over the surfaces of the bonding pads.

7. The method of claim 6 further comprising:
processing the cap layer to form removable portions over surfaces of the exposed bonding pads, wherein the removable portions in the cap layer are wider than the surfaces of the exposed bonding pads; and
developing the cap layer to remove the removable portions therein to form openings with stepped profile side walls that expose the surfaces of the bonding pads.

8. The method of claim 7 further comprising:
depositing a conductive material in the openings to form conductive bumps in the openings on the surfaces of the exposed bonding pads.

9. The method of claim 1 wherein depositing the epoxy-based photoresist on the wafer to form the wall layer comprises:
depositing the epoxy-based photoresist on the wafer to form the wall layer and to extend between adjacent bulk acoustic wave resonator devices.

10. A wafer including an array of bulk acoustic wave resonator devices comprising:
a first bulk acoustic wave resonator device on the wafer, the first bulk acoustic wave resonator device including a passivation layer on a piezoelectric layer;
a second bulk acoustic wave resonator device on the wafer directly adjacent to the first bulk acoustic wave resonator device, the second bulk acoustic wave resonator device including the passivation layer and the piezoelectric layer;
a wall layer on the wafer forming first and second wall cavity structures that extend around the first and second bulk acoustic wave resonator devices, respectively;
a capping layer extending over the wall layer to cover the first and second wall cavity structures that include the first and second bulk acoustic wave resonator devices, respectively;
a metallization layer coupling together bulk acoustic wave resonators included in the first or second bulk acoustic wave resonator device; and
a pillar that protrudes vertically from the metallization layer to contact the cap layer.

11. A packaged device comprising:
a piezoelectric layer included in a bulk acoustic wave resonator device;
a passivation layer included in a bulk acoustic wave resonator device on the piezoelectric layer;
first and second bonding pads on the passivation layer, the first and second bonding pads coupled to the bulk acoustic wave resonator device;
an epoxy-based photoresist wall layer on the passivation layer extending from the first bonding pad around the bulk acoustic wave resonator device to the second bonding pad;
an epoxy-based photoresist capping layer extending on the wall layer over the bulk acoustic wave resonator device to form a wall cavity structure that contains the bulk acoustic wave resonator device;
a first opening through the capping layer and through the wall layer to expose the first bonding pad; and
a second opening through the capping layer and through the wall layer to expose the second bonding pad.
